(19) United States
(12) Patent Application Publication
(10) Pub. No.: US 2026/0026092 A1
(43) Pub. Date: Jan. 22, 2026

(54) SEMICONDUCTOR DEVICE

(71) Applicant: Samsung Electronics Co., Ltd., Suwon-si (KR)

(72) Inventors: Jisoo Park, Suwon-si (KR); Junghan Lee, Suwon-si (KR); Byungsung Kim, Suwon-si (KR); Kwanyoung Chun, Suwon-si (KR)

(21) Appl. No.: 19/238,617

(22) Filed: Jun. 16, 2025

(30) Foreign Application Priority Data
Jul. 19, 2024 (KR) 10-2024-0095586

(51) Int. Cl. H10D 84/83; H01L 23/528; H10D 30/00; H10D 62/10; H10D 62/13; H10D 64/23

(52) U.S. Cl. CPC H10D 84/833; H01L 23/5283; H10D 30/503; H10D 30/506; H10D 62/102; H10D 62/121; H10D 62/127; H10D 62/151; H10D 64/256; H10D 84/8311; H10D 84/8312; H10D 84/83138

(57) ABSTRACT

A semiconductor device includes an active pattern extending on a substrate in a first direction, channel patterns vertically stacked on the active pattern, a separation structure extending in a second direction and separating each of the active pattern and the channel patterns into first and second portions, a gate structure extending in the second direction and onto the first portions of the channel patterns, a separation pattern extending in the first direction, separating the first portions of the channel patterns into first and second channel patterns, and separating the gate structure into first and second gate structures, and a third gate structure extending in the second direction and onto the second portions of the channel patterns. The second portions of the channel patterns have a width greater than a sum of first and second widths of the first and second channel patterns, respectively.

### CROSS-REFERENCE TO RELATED APPLICATION(S)

This application claims benefit of priority to Korean Patent Application No. 10-2024-0095586 filed on Jul. 19, 2024, in the Korean Intellectual Property Office, the disclosure of which is incorporated herein by reference in its entirety.

### TECHNICAL FIELD

The present inventive concept relates to a semiconductor device.

### BACKGROUND

As demand for implementation of high performance, high speed, and/or multifunctionality of semiconductor devices increases, a degree of integration of semiconductor devices has been increasing. In accordance with a high degree of integration of semiconductor devices, semiconductor devices may have lowered or degraded operating properties. Accordingly, various methods of forming a semiconductor device having excellent performance, while overcoming limitations caused by a high degree of integration of semiconductor devices, have been researched. For example, in order to overcome limitations on operating properties caused by scaling down, semiconductor devices having three-dimensional channel structures have been developed.

### SUMMARY

An aspect of the present inventive concept provides a semiconductor device having a high degree of integration and improved electrical properties.

According to an aspect of the present inventive concept, a semiconductor device includes a first cell and a second cell in a first row and a second row, respectively, where the first row and the second row extend in a first direction, and the first row and the second row are adjacent to each other in a second direction that intersects the first direction; a merged cell extending in the second direction across the first and second rows, where the merged cell is adjacent to the first and second cells in the first direction; a separation pattern extending in the first direction at a boundary between the first and second cells, the separation pattern having a first side surface and a second side surface facing the first cell and the second cell, respectively; and at least one separation structure extending in the second direction between the first and second cells and the merged cell. The first cell comprises a first active pattern extending in the first direction along the first side surface of the separation pattern, first channel patterns adjacent to the first side surface of the separation pattern, the first channel patterns stacked on the first active pattern and spaced apart from each other in a third direction that is perpendicular to the first and second directions, a first gate structure extending in the second direction and on the first channel patterns, and first source/drain patterns respectively connected to opposing sides of the first channel patterns in the first direction. The second cell comprises a second active pattern extending in the first direction along the second side surface of the separation pattern, second channel patterns adjacent to the second side surface of the separation pattern, the second channel patterns stacked on the second active pattern and spaced apart from each other in the third direction, a second gate structure separated from the first gate structure by the separation pattern, the second gate structure extending in the second direction and on the second channel patterns, and second source/drain patterns respectively connected to opposing sides of the second channel patterns in the first direction. The merged cell comprises a third active pattern separated from the first and second active patterns by the separation structure, the third active pattern extending in the first direction, third channel patterns stacked on the third active pattern and spaced apart from each other in the third direction, a third gate structure extending in the second direction and on the third channel patterns, and third source/drain patterns respectively connected to opposing sides of the third channel patterns in the first direction.

According to another aspect of the present inventive concept, a semiconductor device includes a first cell and a second cell in a first row and a second row, respectively, where the first row and the second row extend in a first direction, and the first row and the second row are adjacent to each other in a second direction that intersects the first direction; a merged cell extending in the second direction across the first and second rows, where the merged cell is adjacent to the first and second cells in the first direction; and a separation pattern extending in the first direction at a boundary between the first and second cells, the separation pattern having a first side surface and a second side surface facing the first cell and the second cell, respectively. The first cell comprises a first active pattern extending in the first direction along the first side surface of the separation pattern, and first channel patterns adjacent to the first side surface of the separation pattern, the first channel patterns stacked on the first active pattern and spaced apart from each other in a third direction that is perpendicular to the first and second directions. The second cell comprises a second active pattern extending in the first direction along the second side surface of the separation pattern, and second channel patterns adjacent to the second side surface of the separation pattern, the second channel patterns stacked on the second active pattern and spaced apart from each other in the third direction. The merged cell comprises a third active pattern overlapping at least a portion of each of the first and second active patterns in the first direction, the third active pattern extending in the first direction, and third channel patterns stacked on the third active pattern and spaced apart from each other in the third direction. A width of the third active pattern in the second direction is greater than a sum of respective widths of the first and second active patterns in the second direction.

According to another aspect of the present inventive concept, a semiconductor device includes an active pattern extending on a substrate in a first direction; a separation structure extending in a second direction that intersects the first direction; channel patterns stacked on the active pattern and spaced apart from each other in a third direction that is perpendicular to the first and second directions, where the separation structure separates each of the active pattern and the channel patterns into first and second portions; a gate structure extending in the second direction and onto the first portions of the channel patterns; a separation pattern extending in the first direction, where the separation pattern separates the first portions of the channel patterns into first and second channel patterns, and separates the gate structure into first and second gate structures; and a third gate structure extending in the second direction and onto the second portions of the channel patterns. The second portions of the channel patterns have a width in the second direction that is greater than a sum of first and second widths of the first and second channel patterns, respectively, in the second direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an example embodiment of the present inventive concept;

FIGS. 2A and 2B are cross-sectional views of the semiconductor device illustrated in FIG. 1, taken along lines I1-I1′ and 12-12′, respectively;

FIGS. 3A and 3B are cross-sectional views of the semiconductor device illustrated in FIG. 1, taken along lines II1-II1′ and II2-II2′, respectively;

FIGS. 4A and 4B are cross-sectional views of the semiconductor device illustrated in FIG. 1, taken along lines III1-III1′ and III2-III2′, respectively;

FIG. 5 is a plan view of a semiconductor device according to an example embodiment of the present inventive concept;

FIGS. 6A and 6B are cross-sectional views of the semiconductor device illustrated in FIG. 5, taken along lines II1-II1′ and II2-II2′, respectively;

FIG. 7 is a plan view of a semiconductor device according to an example embodiment of the present inventive concept;

FIGS. 8A and 8B are cross-sectional views of the semiconductor device illustrated in FIG. 7, taken along lines I1-I1′ and I2-I2′, respectively; and

FIGS. 9 and 10 are plan views of a semiconductor device according to various example embodiments of the present inventive concept.

### DETAILED DESCRIPTION

Hereinafter, various example embodiments of the present inventive concept will be described in detail with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

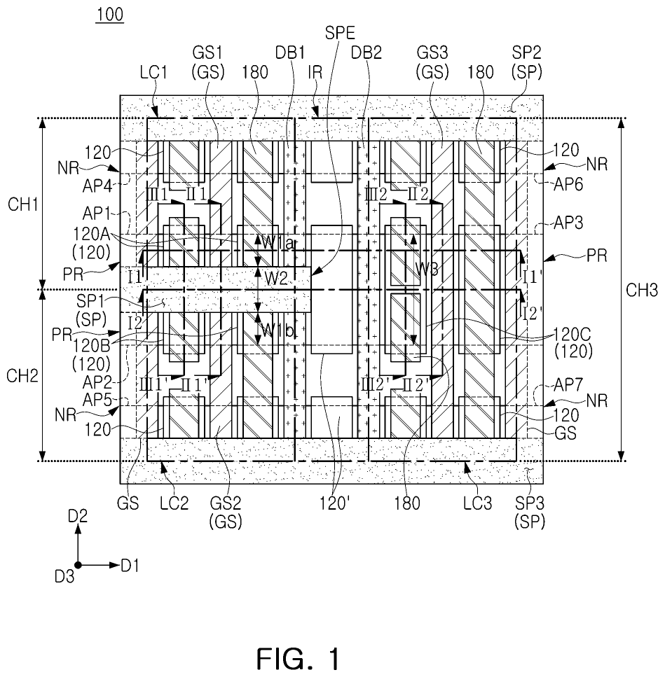

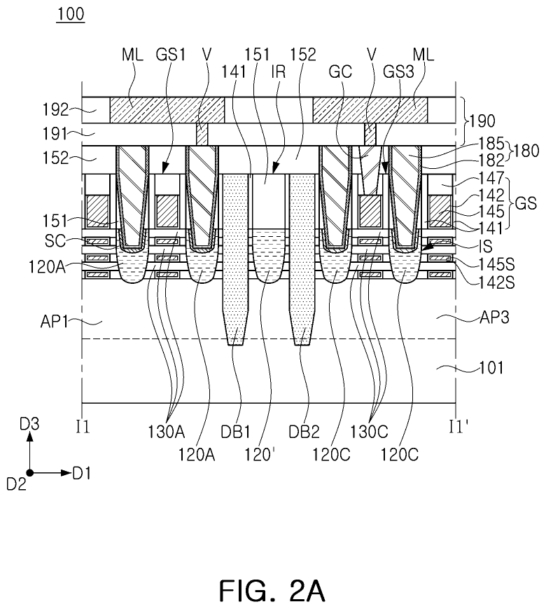

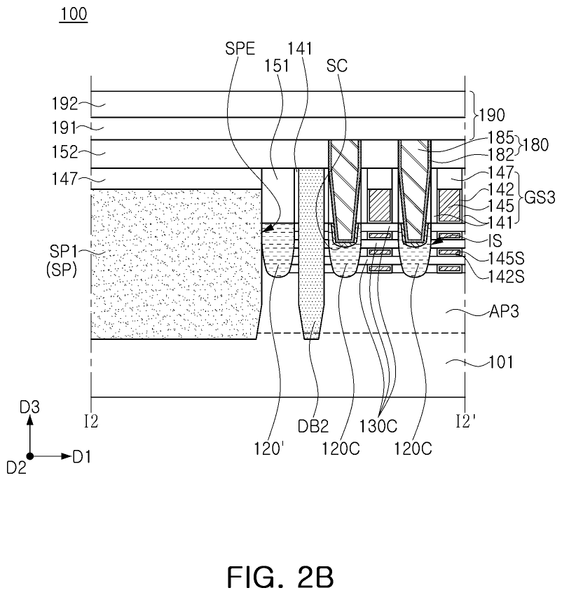

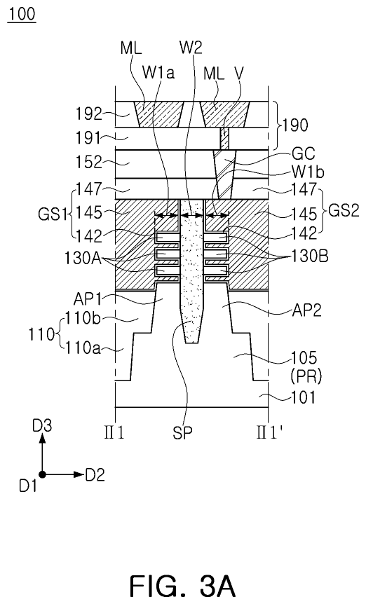

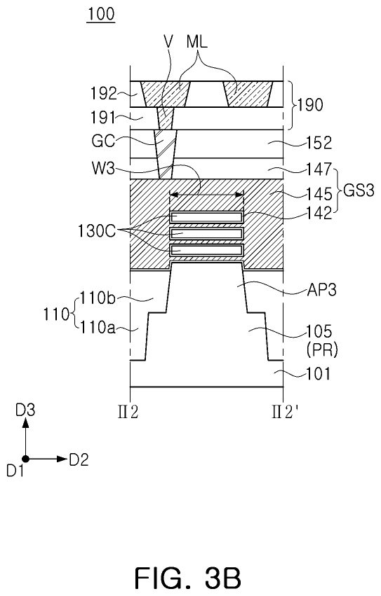

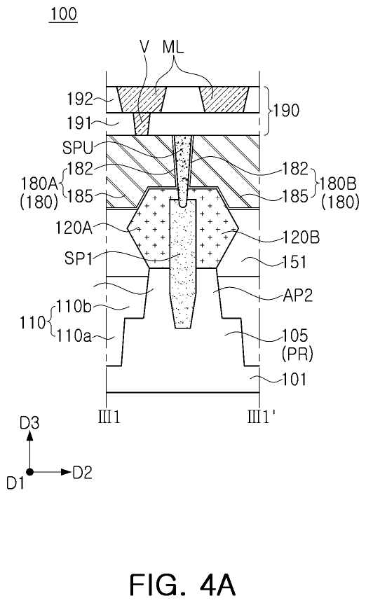

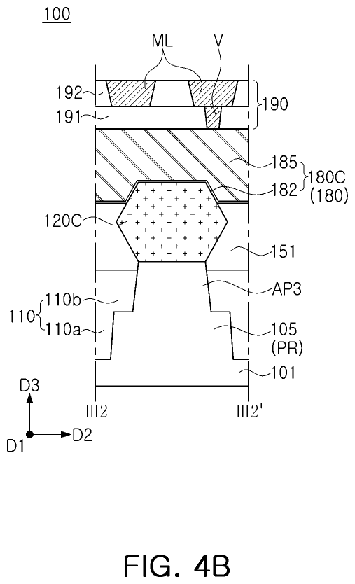

FIG. 1 is a plan view of a semiconductor device according to an example embodiment of the present inventive concept. FIGS. 2A and 2B are cross-sectional views of the semiconductor device illustrated in FIG. 1, taken along lines I1-I1′ and I2-I2′, respectively. FIGS. 3A and 3B are cross-sectional views of the semiconductor device illustrated in FIG. 1, taken along lines III-II1′ and II2-II2′, respectively. FIGS. 4A and 4B are cross-sectional views of the semiconductor device illustrated in FIG. 1, taken along lines III1-III1′ and III2-III2′, respectively.

Referring to FIG. 1, a semiconductor device 100 according to the present example embodiment may include a first cell LC1, a second cell LC2, and a third cell LC3, disposed on a substrate 101. The first and second cells LC1 and LC2 may be respectively disposed in a first row and a second row extending in a first direction D1, the first row and the second row adjacent to each other, and may be arranged to be parallel to each other in a second direction D2, intersecting the first direction D1. The third cell may be a merged cell adjacent to the first and second cells LC1 and LC2 across the first and second rows. Here, the third cell LC3 may also be referred to as a merged cell.

Logic transistors, included in a logic circuit, may be disposed in each of the first and second cells LC1 and LC2 and the merged cell LC3. The first and second cells LC1 and LC2 may include the same or different logic circuits, and the first and second cells LC1 and LC2 may also be referred to as first and second logic cells, respectively. In the present example embodiment, the first and second cells LC1 and LC2 may have first and second cell heights CH1 and CH2, respectively, and the first and second cell heights CH1 and CH2 may be the same or different from each other. The merged cell LC3 may have a cell height CH3 corresponding to a sum (CH1+CH2) of the first and second cell heights.

The substrate 101 may include, for example, a semiconductor such as Si or Ge, or a compound semiconductor such as SiGe, SiC, GaAs, InAs or InP. In another example, the substrate 101 may have a silicon-on-insulator (SOI) structure. The substrate 101 may include an active region 105, and may include, for example, a well doped with a specific conductivity-type impurity. A plurality of active patterns AP, extending in the first direction (for example, a direction of D1), may be respectively disposed on the active region 105, and each of the active patterns AP may have a protruding fin-type structure.

The isolation layer 110 may be disposed on the substrate 101 to define active regions 105 including active patterns AP. For example, the isolation layer 110 may include silicon oxide or a silicon oxide-based insulating material. In the present example embodiment, the isolation layer 110 may be a first isolation layer 110a (also referred to as deep trench isolation (DTI)) defining the active region 105, and a second isolation layer 110b (also referred to as shallow trench isolation (STI)) defining the active patterns AP (see FIGS. 3A and 3B).

Referring to FIG. 1, the active region 105 of the substrate 101 may be divided into a PMOSFET region PR and an NMOSFET region NR. Each of the first cell LC1 and the second cell LC2 may include a PMOSFET region PR and an NMOSFET region NR arranged in the second direction D2. The PMOSFET region PR and the NMOSFET region NR may be separated from each other by the first isolation layer 110a.

In the present example embodiment, the PMOSFET regions PR of the first and second cells LC1 and LC2 may be disposed to oppose each other, and may be provided as a single active region across a cell boundary. Alternatively, in some example embodiments, the NMOSFET regions NR of the first and second cells LC1 and LC2 may be disposed to oppose each other.

The substrate 101 may include a separation region IR between the first and second cells LC1 and LC2 and the merged cell LC3. In the present example embodiment, the separation region may be defined as a region between first and second separation structures DB1 and DB2. The first separation structure DB1 may be disposed to be adjacent to the first and second cells LC1 and LC2, and the second separation structure DB2 may be disposed to be adjacent to the merged cell LC3. The first and second separation structures DB may extend in the second direction D2 in a similar manner to the gate structures GS, and may be arranged in the first direction D1 to have a pitch, the same as that of the gate structures GS.

The first and second separation structures DB1 and DB2 may be lower than (relative to the substrate 101) lower ends of source/drain patterns 120 (for example, first and third source/drain patterns 120A and 120C of FIG. 2A) in a third direction D3, also referred to as a vertical direction. Spatially relative terms such as ‘above,’ ‘upper,’ ‘below,’ ‘lower,’ ‘side,’ and the like may be denoted by reference numerals and refer to the drawings, except where otherwise indicated. It will be understood that such spatially relative terms are intended to encompass different orientations of the device in use or operation in addition to the orientation depicted in the figures. In the present example embodiment, the first and second separation structures DB1 and DB2 may extend to a depth, lower than that of lower ends of the active patterns AP, in the third direction D3. Active patterns, extending across other cells in the first direction D1, may be separated into active patterns AP1, AP2, AP4, and AP5 of the first and second cells LC1 and LC2 and active patterns AP3, AP6, and AP7 of the merged cell LC3 by the first and second separation structures DB1 and DB2. The first and second separation structures DB1 and DB2 may extend in the second direction D2 to cross first and second active patterns AP1 and AP2 and a third active patterns AP3, to cross a fourth active pattern AP4 and a sixth active pattern AP6, and to cross fifth and seventh active patterns AP5 and AP7.

In the present example embodiment, an epitaxial pattern 120′ may be disposed on an active pattern between the first and second separation structures DB1 and DB2. A gate spacer 141 may be disposed on an upper sidewall of each of the first and second separation structures DB1 and DB2. Lower surfaces of the first and second separation structures DB1 and DB2 may be positioned on a level that is higher than that of a lower surface of the isolation layer 110, relative to the substrate 101. The term “level” may be used herein to refer to a distance (e.g., in the vertical direction D3) from a reference surface or element (e.g., the substrate 101). In some example embodiments, lower surfaces of the first and second separation structures DB1 and DB2 may be positioned on a level that is lower than that of a lower surface of the second isolation layer 101b, relative to the substrate 101. Upper surfaces of the first and second separation structures DB1 and DB2 may be coplanar with an upper surface of a gate capping layer 147 and an upper surface of the gate spacer 141. The first and second separation structures DB1 and DB2 may include a material, different from that of the isolation layer 110. For example, the first and second separation structures DB1 and DB2 may include silicon nitride.

As described above, a plurality of active patterns APs may extend on the substrate 101 in the first direction D1, and may be portions of the substrate 101 protruding in the third direction D3.

The first cell LC1 may have a first active pattern AP1 and a third active pattern AP3, and the second cell may have a second active pattern AP2 and a fourth active pattern AP4. The first and second active patterns AP1 and AP2 may be arranged to oppose each other, e.g., in the second direction. The merged cell may include a third active pattern AP3 overlapping a combination of the first and second active patterns AP1 and AP2 in the first direction D1, and sixth and seventh active patterns AP6 and AP7 respectively overlapping the fourth and fifth active patterns AP4 and AP5 in the first direction D1. Here, active patterns, overlapping each other in the first direction D1, may be understood as patterns derived from a single active pattern by the first and second separation structures DB1 and DB2 extending in the second direction D2. More generally, components or layers described with reference to “overlap” in a particular direction may be at least partially obstructed by one another when viewed along a line extending in the particular direction or in a plane perpendicular to the particular direction.

Referring to FIGS. 1, 3A, and 4A, the first and second active patterns AP1 and AP2 may be separated from each other by a first separation pattern SP1 extending in the first direction D1 along a boundary between the first and second cells LC1 and LC2. The first separation pattern SP1 may have a first side surface and a second side surface facing or toward the first cell LC1 and the second cell LC2, respectively, and may be formed to have a depth the same as or similar or to those of the first and second separation structures DB1 and DB2 (see FIG. 2B). The first active pattern AP1 may extend in the first direction D1 along the first side surface of the first separation pattern SP1, and the second active pattern AP2 may extend in the first direction D1 along the second side surface of the first separation pattern SP1.

Referring to FIG. 3A, first channel patterns 130A may be vertically stacked on the first active pattern AP1 to be spaced apart from each other in the third direction D3, and second channel patterns 130B may be vertically stacked on the first active pattern AP2 to be spaced apart from each other in the third direction D3. The first and second channel patterns 130A and 130B may also be separated from each other by the first separation pattern SP1 in a similar manner to the first and second active patterns AP1 and AP2. The first channel patterns 130A may be stacked on the first active pattern AP1 to be adjacent to the first side surface of the first separation pattern SP1, and the second channel patterns 130B may be stacked on the second active pattern AP2 to be adjacent to the second side surface of the first separation pattern SP1. For example, a width of the first channel patterns 130A may be substantially equal to a width of the second channel patterns 130B.

The third active pattern AP3 of the merged cell LC3 may overlap the first and second active patterns AP1 and AP2 in the first direction D1. The third active pattern AP3 may have a width greater than that of each of the first and second active patterns AP1 and AP2. In the present example embodiment, the width of the third active pattern AP3 may be greater than a sum of the respective widths of the first and second active patterns AP1 and AP2, and may be substantially equal to the sum of the respective widths of the first and second active patterns AP1 and AP2 and the width of the separation pattern SP1 therebetween.

Referring to FIGS. 1 and 2B, the first separation pattern SP1 may extend to a space between the first and second active patterns AP1 and AP2 in the first and second cells LC1 and LC2, but may not extend to the merged cell LC3. That is, the merged cell LC3 may be free of the first separation pattern SP1. In the present example embodiment, the first separation pattern SP1 may extend to the epitaxial pattern 120′ across or through the first separation structure DB1. For example, a cross-section SPE of the first separation pattern SP1 may be in contact with the epitaxial pattern 120′. The first and second active patterns AP1 and AP2 may be understood as patterns derived from a single active pattern and separated by the first separation pattern SP1 extending in the first direction D1. In the present example embodiment, the single active pattern may have a width substantially equal to that of the third active pattern AP3.

Referring to FIG. 3B, the third channel patterns 130A may be vertically stacked on the third active pattern AP3 to be spaced apart from each other in the third direction D3. The third channel pattern 130C may have a width W3 greater than a width W1a or W1b of each of the first and second channel patterns in a similar manner to the third active pattern AP3. In the present example embodiment, the width W3 of the third channel pattern 130C may be greater than a sum of the widths W1a and W1b of the first and second channel patterns 130A and 130B, and may have a width substantially equal to as a sum of the widths W1a and W1b of the first and second channel patterns 130A and 130B and the width W2 of the first separation pattern SP1. The first and second channel patterns 130A and 130B may be patterns derived from channel patterns having a wide width and separated by the first separation pattern SP1 extending in the first direction D1. In the present example embodiment, each of the channel patterns having a wide width may have a width substantially equal to that of the third channel patterns 130C.

As described, a transistor, positioned on an intermediate portion of the merged cell LC3, may secure the third channel patterns 130C having an extended effective width.

Each of the first to third channel patterns 130A, 130B, and 130C according to the present example embodiment may include multiple semiconductor patterns, sequentially stacked. For example, the semiconductor patterns may include silicon (Si), germanium (Ge), or silicon-germanium (SiGe). The number of semiconductor patterns are illustrated as three, but the number and shape of the semiconductor patterns may be changed in various manners.

Referring to FIGS. 1, 2A 2B, 4A, and 4B, first, second, and third source/drain patterns 120A, 120B, and 120C may be provided on the first to third active patterns AP1, AP2, and AP3, respectively.

Referring to FIGS. 1 and 2A, in the first cell LC1, a pair of first source/drain patterns 120A may be disposed on the first active pattern AP1, and may be respectively connected to both (e.g., opposing) sides of the first channel patterns 130A in the first direction D1. In the merged cell LC3, a pair of third source/drain patterns 120C may be disposed on the third active pattern AP3, and may be respectively connected to both (e.g., opposing) sides of the third channel patterns 130C in the first direction D1. Although not illustrated, in a similar manner to the pair of first source/drain patterns 120A, in the second cell LC2, a pair of second source/drain patterns 120B may be disposed on the second active pattern AP2, and may be respectively connected to both (e.g., opposing) sides of the second channel patterns 130B in the first direction D1.

Referring to FIG. 4B, the third source/drain patterns 130C may include an epitaxial pattern grown from one region of the third active pattern AP3 and side surfaces of the third channel patterns 130C. Referring to FIG. 4A, each of the first and second source/drain patterns 130A and 130B may have a structure obtained by a single epitaxial pattern being separated by the first separation pattern SP1.

In the present example embodiment, the single epitaxial pattern may be grown to be similar to growth of the third source/drain patterns 130C before the first separation pattern SP1 is formed. In a subsequent process, the single epitaxial pattern may be separated into the first and second source/drain patterns 120A and 120B by the first separation pattern SP1, together with the first and second channel patterns 130A and 130B. The first to third source/drain patterns 120A, 120B, and 120C may be formed using a selective epitaxial growth (SEG) process. Referring to FIG. 4A, the first and second source/drain patterns 120A and 120B may include an upper separation pattern SPU extending on the first separation pattern SP1 to be separated. The upper separation pattern SPU according to the present example embodiment may be configured to separate a contact structure, connected to the first and second source/drain patterns 120A and 120B, into first and second contact structures 180A and 180B.

The first and second source/drain patterns 120A and 120B may be impurity regions having a first conductivity type (for example, a P-type). The third source/drain patterns 120C may be impurity regions having the first conductivity type (for example, the P-type), same as that of the first and second source/drain patterns 120A and 120B. As a P-type impurity, boron (B), indium (In), gallium (Ga), boron trifluoride (BF3), or the like may be used. The first to third source/drain patterns 120A, 120B, and 120C may include a semiconductor element (for example, SiGe) having a lattice constant greater than that of a semiconductor element of the substrate 101 (in particular, the first to third channel patterns 130A, 130B, and 130C). As a result, the first to third source/drain patterns 120A, 120B, and 120C may provide compressive stress to channel patterns therebetween.

Referring to FIG. 1, the first cell LC1 and the second cell LC2 may respectively include a fourth active pattern AP4 and a fifth active pattern AP5 extending in the first direction D1. Similarly, the merged cell LC3 may include a sixth active pattern AP6 and a seventh active pattern AP7 extending in the first direction D1. The sixth active pattern AP6 may overlap the fourth active pattern AP4 in the first direction D1, and the seventh active pattern AP7 may overlap the fifth active pattern AP5 in the first direction D1. The fourth to seventh active patterns AP4, AP5, AP6, and AP7 may be positioned in the NMOS region NR, unlike the first to third active patterns AP1, AP2, and AP3. As described above, the first and second separation structures DB1 and DB2 may extend in the second direction to separate the fourth and sixth active patterns AP4 and AP6, and to separate the fifth and seventh active patterns AP5 and AP7 from each other.

The fourth active pattern AP4 and the sixth active pattern AP6 may be disposed to be adjacent to the second separation pattern SP2 extending in the first direction D1 along an upper boundary. In a similar manner to the first and second active patterns AP1 and AP2, the fourth and sixth active patterns AP4 and AP6 may be understood as patterns obtained by separating from active patterns (not illustrated) of other adjacent cells by the second separation pattern SP2. Similarly, the fifth active pattern AP5 and the seventh active pattern AP7 may be disposed to be adjacent to the third separation pattern SP3 extending in the first direction D1 along a lower boundary. In a similar manner to the fourth and sixth active patterns AP4 and AP6, the fifth and seventh active patterns AP5 and AP7 may be understood as patterns obtained by separating other active patterns (not illustrated) of other adjacent cells by the third separation pattern SP3.

As described, the second and third separation patterns SP2 and SP3 may extend to or into the merged cell LC3 after passing through the first and second cells LC1 and LC2 along the upper boundary and the lower boundary, respectively. Conversely, the first separation pattern SP1 described above may separate the first and second active patterns AP1 and AP2 from each other at the boundary between the first and second cells LC1 and LC2, but may not extend to or into the merged cell LC3. As a result, the semiconductor device 100 according to the present example embodiment may have the third active pattern AP3 having a relatively wide width and the third channel patterns 130C having a relatively wide width, in the merged cell LC3, which is free of the first separation pattern SP1.

The first cell LC1 may include fourth channel patterns (not illustrated) vertically stacked on the fourth active pattern AP4 to be spaced apart from each other in the third direction D3, and fourth source/drain patterns 120 respectively connected to both (e.g., opposing) sides of the fourth channel patterns (not illustrated) in the first direction D1. Similarly, the second cell LC2 may include fifth channel patterns (not illustrated) vertically stacked on the fifth active pattern AP5 to be spaced apart from each other in the third direction D3, and fifth source/drain patterns 120 respectively connected to both (e.g., opposing) sides of the fifth channel patterns (not illustrated) in the first direction D1.

The merged cell LC3 may include sixth and seventh channel patterns (not illustrated) respectively disposed on the sixth and seventh active patterns AP6 and AP7, the sixth and seventh channel patterns vertically stacked to be spaced apart from each other in the third direction D3, sixth source/drain patterns 120 respectively connected to both (e.g., opposing) sides of the sixth channel pattern (not illustrated) in the first direction D1, on the sixth active pattern AP6, and seventh source/drain patterns 120 respectively connected to both (e.g., opposing) sides of the seventh channel pattern (not illustrated) in the first direction D1, on the seventh active pattern AP7.

In the present example embodiment, the fourth and fifth source/drain patterns may have a conductivity type, different from that of the first and second source/drain patterns, and the sixth and seventh source/drain patterns may have a conductivity type, different from that of the third source/drain patterns.

The fourth to seventh source/drain patterns 120 may be impurity regions having a second conductivity type (for example, an N-type). For example, the fourth to seventh source/drain patterns 120 may include Si, and an N-type impurity may include phosphorus (P), nitrogen (N), arsenic (As), and/or antimony (Sb).

Referring to FIGS. 1, 2A, 2B, 3A, and 3B, the semiconductor device 100 according to the present example embodiment may include a first gate structure GSI extending in the second direction D2 in the first cell LC1, the first gate structure GS surrounding the first channel patterns 130A, a second gate structure GS2 extending in the second direction D2 in the second cell, the second gate structure GS2 surrounding the second channel patterns 130B, and a third gate structure GS3 extending in the second direction D2 in the merged cell LC3, the third gate structure GS3 surrounding the third channel patterns 130C. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout. The first and second gate structures GS1 and GS2 may overlap each other in the second direction D2, and may be separated from each other by the first separation pattern SP1 (in particular, see FIG. 3A).

Similarly, referring to FIG. 1, the first gate structure GS1 may extend in the second direction D2 toward the second separation pattern SP2 to surround the fourth channel patterns, and the second gate structure GS2 may extend in the second direction D2 toward the third separation pattern SP3 to surround the fifth channel patterns (not illustrated). In addition, the third gate structure GS3 may extend in the second direction toward the second and third separation patterns SP2 and SP3 to surround the sixth and seventh channel patterns (not illustrated).

As illustrated in FIGS. 2A, 2B, 3A and 3B, the first to third gate structures GS1, GS2, and GS3 may include a gate electrode 145 extending in the second direction D2, the gate electrode 145 surrounding the first to third channel patterns 130A, 130B, and 130C, a gate insulating film 142 disposed between the gate electrode 145 and the related channel patterns 130A, 130B, and 130C, gate spacers 141 disposed on both (e.g., opposing) side surfaces of a portion of the gate electrode 145 positioned on an uppermost semiconductor pattern, and a gate capping layer 147 disposed on the gate electrode 145 between the gate spacers 141.

The gate electrode 145 may include a conductive material. For example, the gate electrode 145 may include at least one of W, Ti, Ta, Mo, TiN, TaN, WN, TiON, TiAlC, TiAlN, and TaAlC. In some example embodiments, the gate electrode 145 may include a semiconductor material such as doped polysilicon. At least one of the gate electrodes 145 may include a multilayer structure, formed of different materials.

The gate insulating film 142 may include a dielectric material. For example, the gate insulating film 142 may include oxide, nitride, or a high-k material. The high-material may refer to a dielectric material having a dielectric constant higher than that of a silicon oxide film (SiO₂), and the high-K material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum aluminum oxide (La₂O₃), lanthanum aluminum oxide (LaAlₓO_{y}), lanthanum hafnium oxide (LaHfₓO_{y}), hafnium aluminum oxide (HfAlₓO_{y}), and prascodymium oxide (Pr₂O₃). In some example embodiments, the gate insulating film 142 may include two or more other dielectric layers.

The gate spacers 141 may include an insulating material. For example, the gate spacers 141 may include at least one of silicon oxide, silicon nitride, and silicon oxynitride. In some example embodiments, the gate spacers 141 may include a multilayer structure, formed of different materials. The gate capping layer 147 may include, for example, silicon nitride, silicon oxynitride, silicon carbide, or silicon oxynitride.

The first to third gate structures GS1, GS2, and GS3 according to the present example embodiment may include internal spacers IS. The internal spacers IS may be respectively disposed on both (e.g., opposing) sides of gate electrode portions 145S positioned between the channel patterns 130A, 130B, and 130C. For example, the internal spacers IS may include a low-K dielectric such as oxide, nitride, and oxynitride. In some example embodiments, the gate electrode portions 145S may be surrounded by gate insulating portions 142S in the first direction D1. The gate electrode portions 145S and the gate insulating portions 142S may be spaced apart from the first to third source/drain patterns 120A, 120B, and 120C by the internal spacers IS. The internal spacers IS may have convex side surfaces toward the gate electrode portions 145S, but the present inventive concept is not limited thereto.

As a result, three P-type transistors may be formed in the PMOSFET region PR, and four N-type transistors may be formed in the NMOSFET region NR.

The semiconductor device 100 according to the present example embodiment may further include a first interlayer insulating layer 151 disposed on the isolation layer 110 to cover the source/drain patterns 120, and a second interlayer insulating layer 152 covering the gate structure GS on the first interlayer insulating layer 151. For example, the first and second interlayer insulating layers 151 and 152 may include a spin-on hardmask (SOH), flowable oxide (FOX), tonen silazen (TOSZ), undoped silica glass (USG), borosilica glass (BSG) phosphosilica glass (PSG), borophosphosilica glass (BPSG), plasma-enhanced tetra ethyl ortho silicate (PETEOS), fluid silicate glass (FSG), high-density plasma (HDP) oxide, plasma-enhanced oxide (PEOX), flowable CVD (FCVD) oxide, or combinations thereof. Each of the first and second interlayer insulating layers 151 and 152 may be formed using a chemical vapor deposition process, a fluid CVD process, or a spin coating process.

The semiconductor device 100 according to the present example embodiment may include contact structures 180 respectively connected to the source/drain patterns 120 passing through the interlayer insulating layer 150 between the gate structures GS. Each of the contact structures 180 may include a contact plug 185 and a barrier layer 182 surrounding the contact plug 185. For example, the contact plug 185 may include Cu, Co, Mo, Ru, W, or an alloy thereof. For example, the barrier layer 182 may include Ta, TaN, Mn, MnN, WN, Ti, TiN, or combinations thereof.

A metal-semiconductor compound layer SC may be disposed between the contact structures 180 and the source/drain patterns 120, respectively. The contact structures 180 may have low-resistance contact with the source/drain patterns 120 by the metal-semiconductor compound layer SC. The metal-semiconductor compound layer SC may include metal-silicide, and may include, for example, at least one of titanium-silicide, tantalum-silicide, tungsten-silicide, nickel-silicide, and cobalt-silicide.

Referring to FIG. 4A, the first and second contact structures 180A and 180B may be respectively connected to the first and second source/drain patterns 120A and 120B, separated from each other by the first separation pattern SP1. The first and second contact structures 180A and 180B may be separated from each other by an upper separation pattern SPU connected to the first separation pattern SP1, and may be electrically connected to the first and second source/drain patterns 120A and 120B, respectively. Referring to FIG. 4B, the third contact structures 180C may be respectively connected to the third source/drain patterns 120C. The gate contact GC may pass through the second interlayer insulating layer 152 and the gate capping layer 147, and may be connected to the gate electrode 145.

The semiconductor device 100 according to the present example embodiment may include an interconnection structure 190. The interconnection structure 190 may be provided on a frontside of the semiconductor device 100. The interconnection structure 190 may include first and second interconnection insulating layers 191 and 192, an interconnection line ML disposed in the second interconnection insulating layer 191, and an interconnection via V passing through the first interconnection insulating layer 191, the interconnection via V connected to the interconnection line. The interconnection line ML and the via V may be formed using a dual damascene process. The interconnection line ML may be connected to each of the contact structure 180 and the gate contact GC by the via V. For example, the first and second interconnection insulating layers 191 and 192 may include a low-K material such as silicon oxide, silicon oxynitride, SiOC, or SiCOH. For example, the interconnection lines ML and the via V may include copper or a copper-containing alloy.

In an example embodiment of the present inventive concept, although not illustrated, interconnection lines, stacked on an additional interconnection insulating layer, may be additionally provided. The stacked interconnection lines may include routing lines and power lines. For example, the power line may be disposed on boundaries between the first and second cells.

According to the above-described example embodiment, the first separation pattern SP1, separating the first and second gate structures GS1 and GS2 and the first and second channel patterns 130A and 130B from each other along the boundary between the first and second cells LC1 and LC2, may not extend into the merged cell LC3, thereby implementing a merged cell LC3 having no separation pattern. In other words, the merged cell LC3 may be free of the separation pattern SP1, and the third gate structure GS3 may continuously extend (without separation) between boundaries of the merged cell LC3 (e.g., as defined by the second and third separation patterns SP2 and SP3) in the second direction D2. As a result, the third channel patterns 130A (and the third active pattern AP3) of the merged cell LC3, overlapping the first and second channel patterns 130A and 130B (and the first and second active patterns AP1 and AP2) in the first direction D1, may have a sufficient effective width.

In addition, unlike the present example embodiment, when the first separation pattern SP1 is extended to the merged cell LC3, the third gate structure GS3 may be separated into two gate structures, and thus electrical connection between the separated gate structures (e.g., by providing an additional gate connection pattern) may be required. Accordingly, in the present example embodiment, an increase in resistance caused by the additional gate connection pattern or other electrical connection between the separated gate structures may be prevented.

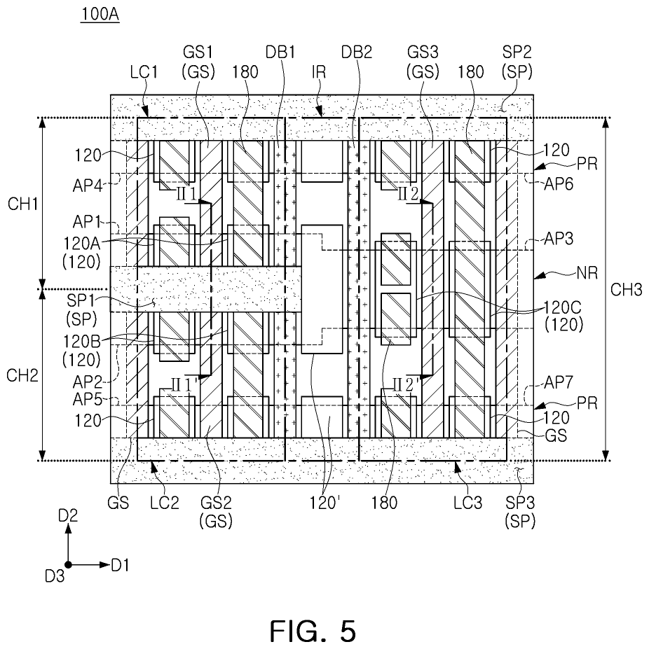

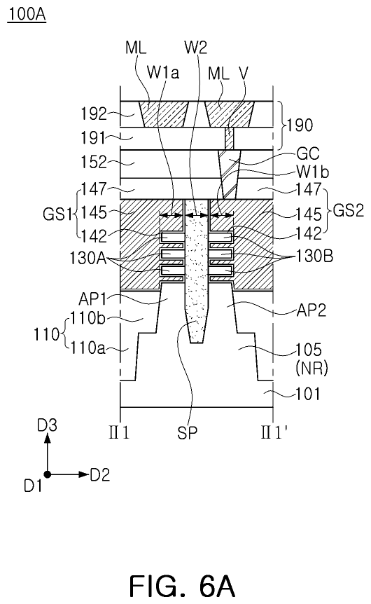

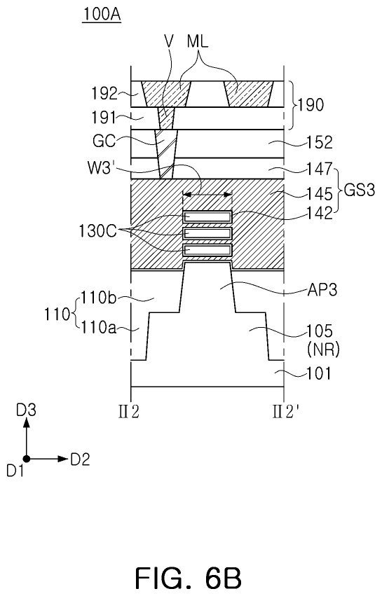

FIG. 5 is a plan view of a semiconductor device according to an example embodiment of the present inventive concept. FIGS. 6A and 6B are cross-sectional views of the semiconductor device illustrated in FIG. 5, taken along lines II1-II1′ and II2-II2′, respectively. Referring to FIGS. 5, 6A, and 6B, a semiconductor device 100A according to the present example embodiment may be understood to have a structure similar to that of the semiconductor device 100 illustrated in FIGS. 1 to 4B, except that arrangements of an NMOSFET region NR and a PMOSFET region PR in each of cells LC1, LC2, and LC3 are reversed, and that a width W3′ of an third active pattern AP3 of a merged cell LC3 is slightly less than a sum of widths (W1a+W1b+W2) of first and second active patterns AP1 and AP2 and a first separation pattern SP1. In addition, components of the present example embodiment may be understood with reference to the descriptions of the same or similar components of the semiconductor device 100 illustrated in FIGS. 1 to 4B, unless otherwise described.

In the present example embodiment, an active region 105 of the substrate 101 may be divided into a PMOSFET region PR and an NMOSFET region NR, and each of a first cell LC1 and a second cell LC2 may include a PMOSFET region PR and an NMOSFET region NR arranged in a second direction D2. As illustrated in FIG. 5, the NMOSFET regions NR of the first and second cells LC1 and LC2 may be disposed to oppose each other, and may be provided as a single active region in which the first and second active patterns are disposed across a cell boundary. A third active pattern of a merged cell may overlap first and second active patterns in a first direction, and may be provided as an NMOSFET region NR. First and second source/drain patterns 120A and 120B and third source/drain patterns 120C may be impurity regions having a second conductivity type (for example, an N-type), respectively, and the active patterns of the first and second cells LC1 and LC2 and the merged cell LC3, that is, source/drain patterns 120 respectively disposed on fourth to seventh active patterns AP4, AP5, AP6, and AP7, may be impurity regions having a first conductivity type (for example, a P-type).

In the present example embodiment, a width W3′ of a third channel patterns 130C in the second direction D2 may be slightly less than a sum of widths W1a and W1b of the first and second channel patterns 130A and 130B in the second direction D2 and a width W2 of the first separation pattern SP1 in the second direction D2. However, the width W3′ of the third channel patterns 130C may be greater than a sum of the widths WI and W2 of the first and second channel patterns 130A and 130B. A first separation pattern SP1 may be formed between the first and second active patterns AP1 and AP2, such that the first and second channel patterns 130A and 130B may have substantially equal widths (W1a=W1b).

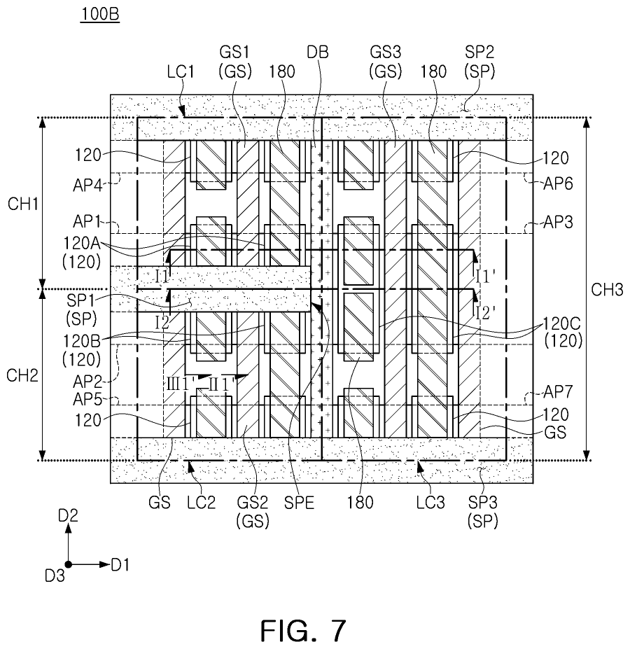

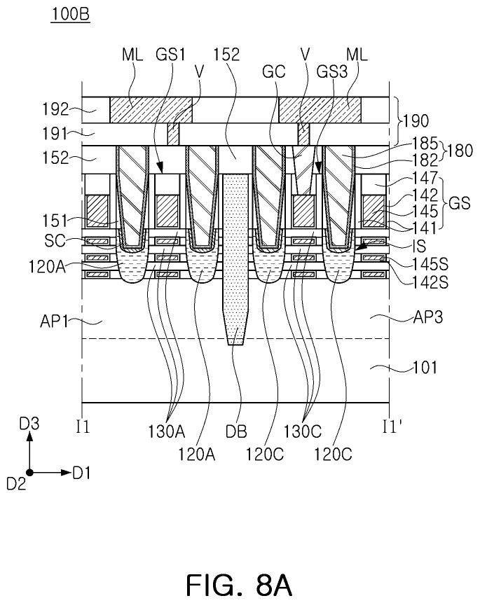

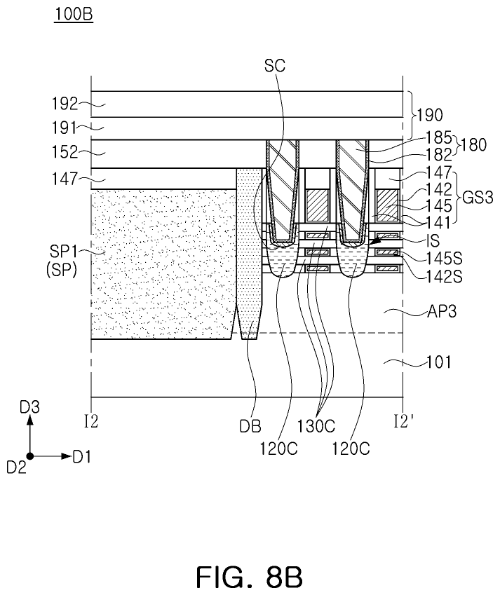

FIG. 7 is a plan view of a semiconductor device according to an example embodiment of the present inventive concept. FIGS. 8A and 8B are cross-sectional views of the semiconductor device illustrated in FIG. 7, taken along lines I1-I1′ and I2-I2′, respectively.

Referring to FIGS. 7, 8A, and 8B, a semiconductor device 100B according to the present example embodiment may be understood to have a structure similar to that of the semiconductor device 100 illustrated in FIGS. 1 to 4B, except that a single separation structure DB is disposed between first and second cells LC1 and LC2 and a merged cell LC3, and that a first separation pattern SP1 extends to the separation structure DB. In addition, components of the present example embodiment may be understood with reference to the descriptions of the same or similar components of the semiconductor device 100 illustrated in FIGS. 1 to 4B, unless otherwise described.

In the present example embodiment, the semiconductor device 100B may include a single separation structure DB extending in the second direction D2 between the first and second cells LC1 and LC2 and the merged cell LC3. The separation structure DB may be arranged to have a pitch, the same as that of gate structures GS in a first direction D1. The separation structures DB may be disposed between first and second active patterns AP1 and AP2 and a third active pattern AP3 to separate the first and second active patterns AP1 and AP2 and the third active pattern AP3 from each other. The separation structures DB may respectively extend to upper and lower boundaries to cross a fourth active pattern AP4 and a sixth active pattern AP6, and to cross a fifth active pattern AP5 and a seventh active pattern AP7.

In the present example embodiment, the first separation pattern SP1 may extend to the separation structure DB, but may not extend therebeyond or into the merged cell LC3. For example, a cross-section SPE of the first separation pattern SP1 may be configured to be in contact with a side surface of the separation structure DB.

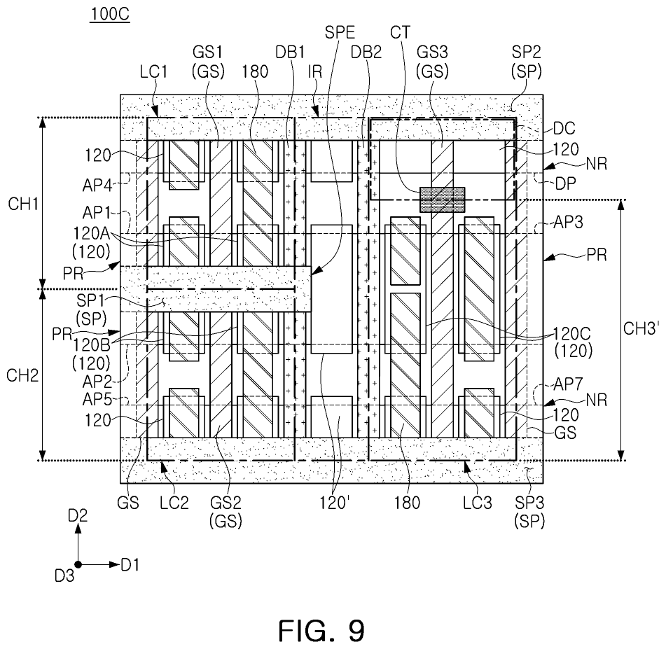

FIG. 9 is a plan view of a semiconductor device according to an example embodiment of the present inventive concept.

Referring to FIG. 9, a semiconductor device 100C according to the present example embodiment may be understood to have a structure similar to that of the semiconductor device 100 illustrated in FIGS. 1 to 4B, except that a gate cut structure CT is formed in a third gate structure GS3, and that a dummy cell DC having a dummy pattern is present in a region adjacent to an upper boundary of a merged cell LC3. In addition, components of the present example embodiment may be understood with reference to the descriptions of the same or similar components of the semiconductor device 100 illustrated in FIGS. 1 to 4B, unless otherwise described.

In the present example embodiment, the merged cell LC3 may include the dummy cell DC in the region adjacent to the upper boundary thereof. The dummy cell DC may not include a transistor. A cell height CH3′ of the merged cell LC3 may be less than a sum (CH1+CH2) of heights of first and second cells LC1 and LC2 by a height of the dummy cell DC. In the third gate structure GS3, the gate cut structure CT may be formed in a region adjacent to an upper boundary thereof and separated into two gate structures. The dummy cell DC may include a dummy pattern DP overlapping a fourth active pattern AP4 of the first cell LC1 in a first direction D1.

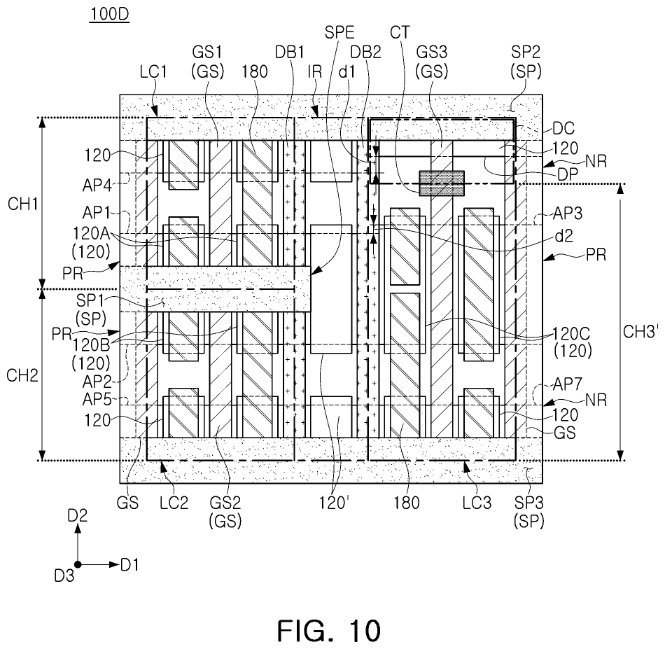

FIG. 10 is a plan view of a semiconductor device according to an example embodiment of the present inventive concept.

Referring to FIG. 10, a semiconductor device 100D according to the present example embodiment may be understood to have a structure similar to that of the semiconductor device 100 illustrated in FIGS. 1 to 4B, except that a width of a third active pattern AP3 increases as a width of a dummy pattern DP decreases, in addition to that a gate cut structure CT is formed in a third gate structure GS3, and that a dummy cell DC is present in a region adjacent to an upper boundary of a merged cell LC3, in a similar manner to the example embodiment of FIG. 9. In addition, components of the present example embodiment may be understood with reference to the descriptions of the same or similar components of the semiconductor device 100 illustrated in FIGS. 1 to 4B, unless otherwise described.

In the present example embodiment, a dummy pattern DP of the dummy cell DC may overlap a fourth active pattern AP4 of a first cell LC1 in a first direction D1. The dummy pattern may not contribute to a configuration of a transistor. A width of a dummy pattern DP may be reduced by a predetermined width d1 in a second direction D2. As illustrated in FIG. 10, a side surface of the dummy pattern DP may be indented toward the third active pattern AP3, such that the dummy pattern DP may have a width less than that of the fourth active pattern AP4 of the first cell LC1. The third active pattern AP3 may have a portion having a surface protruding toward the dummy pattern DP. The third active pattern AP3 may have a width increased in the second direction D2 by a width d2 of the protruding portion.

As described, even when a width of a third active pattern AP3 of a merged cell LC3 is increased, a width of adjacent dummy patterns DP may be reduced, thereby maintaining a separation distance between the third active pattern AP3 and the dummy pattern DP (e.g., in the second direction D2) at a level or distance that is substantially the same as that of a distance between a first active pattern AP1 and the fourth active pattern AP4 (in the direction D2). As a result, in the present example embodiment, a width of third channel patterns (130C of FIG. 3B), stacked on the third active pattern AP3, may be additionally increased to secure a further extended effective channel width.

According to example embodiments of the present inventive concept, a separation pattern formed along a boundary between cells, the separation pattern separating a gate structure and a channel pattern from each other may not extend into a merged cell, thereby implementing a merged cell free of or having no separation pattern. As a result, a sufficient channel width may be secured, and an increase in gate resistance caused by an additional gate connection pattern (which may otherwise be required to provide electrical connection of the gate structure due to extension of the separation pattern into the merged cell) may be prevented.

While example embodiments have been shown and described above, it will be apparent to those skilled in the art that modifications and variations could be made without departing from the scope of the present inventive concept as defined by the appended claims.

What is claimed is:

1. A semiconductor device comprising:
a first cell and a second cell in a first row and a second row, respectively, wherein the first row and the second row extend in a first direction, and the first row and the second row are adjacent to each other in a second direction that intersects the first direction;
a merged cell extending in the second direction across the first and second rows, wherein the merged cell is adjacent to the first and second cells in the first direction;
a separation pattern extending in the first direction at a boundary between the first and second cells, the separation pattern having a first side surface and a second side surface facing the first cell and the second cell, respectively; and
at least one separation structure extending in the second direction between the first and second cells and the merged cell,
wherein the first cell comprises a first active pattern extending in the first direction along the first side surface of the separation pattern, first channel patterns adjacent to the first side surface of the separation pattern, the first channel patterns stacked on the first active pattern and spaced apart from each other in a third direction that is perpendicular to the first and second directions, a first gate structure extending in the second direction and on the first channel patterns, and first source/drain patterns respectively connected to opposing sides of the first channel patterns in the first direction,
wherein the second cell comprises a second active pattern extending in the first direction along the second side surface of the separation pattern, second channel patterns adjacent to the second side surface of the separation pattern, the second channel patterns stacked on the second active pattern and spaced apart from each other in the third direction, a second gate structure separated from the first gate structure by the separation pattern, the second gate structure extending in the second direction and on the second channel patterns, and second source/drain patterns respectively connected to opposing sides of the second channel patterns in the first direction, and
wherein the merged cell comprises a third active pattern separated from the first and second active patterns by the separation structure, the third active pattern extending in the first direction, third channel patterns stacked on the third active pattern and spaced apart from each other in the third direction, a third gate structure extending in the second direction and on the third channel patterns, and third source/drain patterns respectively connected to opposing sides of the third channel patterns in the first direction.

2. The semiconductor device of claim 1, wherein a third width of the third channel patterns in the second direction is greater than a sum of first and second widths of the first and second channel patterns, respectively, in the second direction.

3. The semiconductor device of claim 1, wherein a third width of the third channel patterns in the second direction is equal to a sum of first and second widths of the first and second channel patterns, respectively, in the second direction and a width of the separation pattern in the second direction.

4. The semiconductor device of claim 1, wherein first and second widths of the first and second channel patterns in the second direction are equal to each other.

5. The semiconductor device of claim 1, wherein the at least one separation structure comprises a first separation structure adjacent to the first and second cells, and a second separation structure adjacent to the merged cell.

6. The semiconductor device of claim 5, further comprising:
an epitaxial pattern on the third active pattern between the first and second separation structures,
wherein the separation pattern extends to the epitaxial pattern across the first separation structure, and wherein the merged cell is free of the separation pattern.

7. The semiconductor device of claim 1, wherein
the at least one separation structure comprises a single separation structure separating the third active pattern from the first and second active patterns, and
the separation pattern extends to the single separation structure such that the merged cell is free of the separation pattern.

8. The semiconductor device of claim 1, wherein
the first cell further comprises a fourth active pattern extending in the first direction at a boundary opposite to the boundary between the first and second cells, fourth channel patterns stacked on the fourth active pattern and spaced apart from each other in the third direction, and fourth source/drain patterns respectively connected to opposing sides of the fourth channel patterns in the first direction on the fourth active pattern,
the second cell further comprises a fifth active pattern extending in the first direction at a boundary opposite to the boundary between the first and second cells, fifth channel patterns stacked on the fifth active pattern and spaced apart from each other in the third direction, and fifth source/drain patterns respectively connected to opposing sides of the fifth channel patterns in the first direction on the fifth active pattern, and
the first gate structure extends in the second direction and on the fourth channel patterns, and the second gate structure extends in the second direction and on the fifth channel patterns.

9. The semiconductor device of claim 8, wherein
the first and second source/drain patterns have a first conductivity type, and
the fourth and fifth source/drain patterns have a second conductivity type that is different from the first conductivity type of the first and second source/drain patterns.

10. The semiconductor device of claim 8, wherein the merged cell comprises:
a sixth active pattern extending in the first direction, the sixth active pattern overlapping the fourth active pattern in the first direction, the sixth active pattern separated from the fourth active pattern by the separation structure;
a seventh active pattern extending in the first direction, the seventh active pattern overlapping the fifth active pattern in the first direction, the seventh active pattern separated from the fifth active pattern by the separation structure;
sixth and seventh channel patterns on the sixth and seventh active patterns, respectively, the sixth and seventh channel patterns stacked and spaced apart from each other in the third direction;
sixth source/drain patterns respectively connected to opposing sides of the sixth channel patterns in the first direction on the sixth active pattern; and
seventh source/drain patterns respectively connected to opposing sides of the seventh channel patterns in the first direction on the seventh active pattern,
wherein the third gate structure extends in the second direction and on the sixth and seventh channel patterns.

11. The semiconductor device of claim 10, wherein the sixth and seventh source/drain patterns have a second conductivity type that is different from a first conductivity type of the third source/drain patterns.

12. The semiconductor device of claim 8, wherein the merged cell comprises a dummy pattern extending in the first direction, the dummy pattern overlapping the fourth active pattern in the first direction, the dummy pattern separated from the fourth active pattern by the separation structure.

13. The semiconductor device of claim 12, wherein
a side surface of the dummy pattern facing the third active pattern is idented, such that the dummy pattern has a width that is less than a width of the fourth active pattern in the second direction, and
a portion of the third active pattern protrudes toward the dummy pattern in the second direction, such that a width of the third active pattern in the second direction is increased by the portion that protrudes toward the dummy pattern.

14. A semiconductor device comprising:
a first cell and a second cell in a first row and a second row, respectively, wherein the first row and the second row extend in a first direction, and the first row and the second row are adjacent to each other in a second direction that intersects the first direction;
a merged cell extending in the second direction across the first and second rows, wherein the merged cell is adjacent to the first and second cells in the first direction; and
a separation pattern extending in the first direction at a boundary between the first and second cells, the separation pattern having a first side surface and a second side surface facing the first cell and the second cell, respectively,
wherein the first cell comprises a first active pattern extending in the first direction along the first side surface of the separation pattern, and first channel patterns adjacent to the first side surface of the separation pattern, the first channel patterns stacked on the first active pattern and spaced apart from each other in a third direction that is perpendicular to the first and second directions,
wherein the second cell comprises a second active pattern extending in the first direction along the second side surface of the separation pattern, and second channel patterns adjacent to the second side surface of the separation pattern, the second channel patterns stacked on the second active pattern and spaced apart from each other in the third direction,
wherein the merged cell comprises a third active pattern overlapping at least a portion of each of the first and second active patterns in the first direction, the third active pattern extending in the first direction, and third channel patterns stacked on the third active pattern and spaced apart from each other in the third direction, and
wherein a width of the third active pattern in the second direction is greater than a sum of respective widths of the first and second active patterns in the second direction.

15. The semiconductor device of claim 14, wherein the third active pattern has a width that is equal to a sum of the respective widths of the first and second active patterns and a width of the separation pattern in the second direction.

16. The semiconductor device of claim 14, further comprising:
first and second separation structures extending in the second direction between the first and second cells and the merged cell, wherein the first and second separation structures are spaced apart from each other in the first direction, and
wherein, in the first direction, the first separation structure is adjacent to the first and second cells, and the second separation structure is adjacent to the merged cell.

17. The semiconductor device of claim 16, further comprising:
an epitaxial pattern on the third active pattern between the first and second separation structures,
wherein the separation pattern extends to the epitaxial pattern across the first separation structure, and wherein the merged cell is free of the separation pattern.

18. The semiconductor device of claim 14, further comprising:
a single separation structure separating the third active pattern from the first and second active patterns,
wherein the separation pattern extends to the single separation structure, and wherein the merged cell is free of the separation pattern.

19. A semiconductor device comprising:
an active pattern extending on a substrate in a first direction;
a separation structure extending in a second direction that intersects the first direction;
channel patterns stacked on the active pattern and spaced apart from each other in a third direction that is perpendicular to the first and second directions, wherein the separation structure separates each of the active pattern and the channel patterns into first and second portions;
a gate structure extending in the second direction and onto the first portions of the channel patterns;
a separation pattern extending in the first direction, wherein the separation pattern separates the first portions of the channel patterns into first and second channel patterns, and separates the gate structure into first and second gate structures; and
a third gate structure extending in the second direction and onto the second portions of the channel patterns,
wherein the second portions of the channel patterns have a width in the second direction that is greater than a sum of first and second widths of the first and second channel patterns, respectively, in the second direction.

20. The semiconductor device of claim 19, wherein the width of the second portions of the channel patterns is equal to a sum of the first and second widths of the first and second channel patterns and a width of the separation pattern in the second direction.
